(19) United States
(12) Patent Application Publication
(10) Pub. No.: US 2024/0387348 A1
(43) Pub. Date: Nov. 21, 2024

(54) DISPLAY PANEL, DISPLAY DEVICE AND TILED DISPLAY DEVICE

(71) Applicants: BOE MLED Technology Co., Ltd., Beijing (CN); BOE TECHNOLOGY GROUP CO., LTD., Beijing (CN); BEIJING BOE TECHNOLOGY DEVELOPMENT CO., LTD., Beijing (CN)

(72) Inventors: Chao LIU, Beijing (CN); Mengqing LIU, Beijing (CN); Zhonglan ZHAO, Beijing (CN); Lili WANG, Beijing (CN); Jingping ZHAO, Beijing (CN); Shanshan FENG, Beijing (CN); Mingming JIA, Beijing (CN); Jing WANG, Beijing (CN); Sha FENG, Beijing (CN); Huaimin WANG, Beijing (CN); Qi QI, Beijing (CN); Ming ZHAI, Beijing (CN); Haiwei SUN, Beijing (CN)

(73) Assignees: BOE MLED Technology Co., Ltd., Beijing (CN); BOE TECHNOLOGY GROUP CO., LTD., Beijing (CN); BEIJING BOE TECHNOLOGY DEVELOPMENT CO., LTD., Beijing (CN)

(21) Appl. No.: 18/665,578

(22) Filed: May 16, 2024

Related U.S. Application Data
(63) Continuation of application No. PCT/CN2023/094491, filed on May 16, 2023.

(51) Int. Cl. H01L 23/498; H01L 25/16

(52) U.S. Cl. CPC H01L 23/49838; H01L 25/167

(57) ABSTRACT

A display panel includes a first substrate, first electrodes, connection leads, a connection layer, a second substrate, and second electrodes disposed on a side of the second substrate away from the first substrate. The first substrate includes a first surface and a second surface that are opposite to each other and side surfaces connecting the first and second surfaces. At least one side surface is a selected side surface. The second substrate is disposed on the second surface. The connection layer bonds the first substrate and the second substrate. An orthographic projection of the connection layer on the second surface is located within an orthographic projection of the second substrate on the second surface. The connection leads extend from the first surface to the second surface through the selected side surface. Two ends of a connection lead are connected to a first electrode and a second electrode, respectively.

### CROSS-REFERENCE TO RELATED APPLICATION

This application is a Bypass Continuation Application of International Patent Application No. PCT/CN2023/094491, filed on May 16, 2023, which is incorporated herein by reference in its entirety.

### TECHNICAL FIELD

The present disclosure relates to the field of display technologies, and in particular, to a display panel, a display device and a tiled display device.

### BACKGROUND

The use of micro light-emitting diodes or mini light-emitting diodes as pixels in display panels has usually received widespread attention and research. At present, due to the problem of the yield of mass transfer, a large-sized display device cannot be produced at one time. Generally, the large-sized display device is assembled using a method for tiling small-sized display devices.

In order to reduce the bezel size of the display device and reduce the tilted width of the tilted display device, currently, a single display panel can use the wires arranged on the side surface(s) of the display panel to realize the connection between the wires on the display surface and the driver (such as circuit board or driver chip) arranged on the non-display surface. Therefore, when multiple display panels constitute a larger-sized tiled display device, a distance between adjacent display panels can be small. As a result, the display quality is improved.

### SUMMARY

In an aspect, a display panel is provided. The display panel includes a first substrate, a plurality of first electrodes, a second substrate, a plurality of second electrodes, a plurality of connection leads, and a connection layer. The first substrate includes a first surface and a second surface that are opposite to each other and a plurality of side surfaces connecting the first surface and the second surface, at least one side surface being a selected side surface. The first surface includes a display region and a peripheral region located on at least one side of the display region, the peripheral region being closer to the selected side surface than the display region.

The second substrate is disposed on the second surface, and the plurality of second electrodes are disposed on a side of the second substrate away from the first substrate and disposed proximate to the selected side surface. The first electrodes are disposed in the peripheral region. The connection layer is disposed between the first substrate and the second substrate, and the connection layer bonds the first substrate and the second substrate. An orthographic projection of the connection layer on the second surface being located within an orthographic projection of the second substrate on the second surface. The connection leads extend from the first surface to the second surface through the selected side surface. An end of a connection lead is connected to a first electrode, and another end of the connection lead is connected to a second electrode.

In some embodiments, the connection layer includes at least one groove, and the groove penetrates from an upper surface of the connection layer to the lower surface of the connection layer.

In some embodiments, the groove includes: at least one first groove and/or at least one second groove, the first groove and the second groove extending in different directions. A border of the first groove and a border of the second groove do not overlap a border of the connection layer.

In some embodiments, the groove penetrates the connection layer in a set direction, the set direction being parallel to the lower surface of the connection layer.

In a case where the connection layer includes a plurality of grooves, the plurality of grooves are arranged at intervals.

In some embodiments, in a case where the grooves penetrate the connection layer in a first direction, the grooves are located on a side of the second electrodes away from the selected side surface, the first direction being parallel to the second surface and the selected side surface.

In some embodiments, the grooves are of a grid-like structure.

In some embodiments, a border of the connection layer proximate to the selected side surface overlaps a border of the second proximate to the selected side surface.

In some embodiments, the border of the connection layer proximate to the selected side surface is farther away from the selected side surface than the border of the second substrate proximate to the selected side surface.

In some embodiments, the second substrate includes a body portion and a plurality of protruding portions disposed on a side of the body portion proximate to the selected side surface. An end of a protruding portion is connected to the body portion, and another end of the protruding portion extends toward the selected side surface, and the plurality of the protruding portions are arranged at intervals in the first direction.

In some embodiments, an orthographic projection of the protruding portion on a reference plane overlaps an orthographic projection of at least one second electrode on the reference plane, the reference plane being parallel to the selected side surface.

In some embodiments, the second substrate includes a plurality of first via holes arranged in an array, and the first via holes penetrate from an upper surface of the second substrate to a lower surface of the second substrate.

In some embodiments, the plurality of first via holes are arranged in a plurality of columns in a second direction, and at least one side of two sides of each column of first via holes in the first direction is provided with at least one second electrode. The second direction is perpendicular to a first direction and the selected side surface.

In some embodiments, in the first direction, a size of a first via hole is less than a distance between two second electrodes adjacent to the first via hole.

In some embodiments, the connection layer further includes a plurality of second via holes, the second via holes penetrate from an upper surface of the connection layer to a lower surface of the connection layer, and a second via hole is communicated with a first via hole.

In some embodiments, the display panel further includes a buffer layer disposed on the side of the second substrate away from the first substrate. The buffer layer covers an edge portion of the second substrate proximate to the selected side surface. The connection lead is connected to the second electrode across the buffer layer.

In some embodiments, the buffer layer does not overlap the second electrodes, and the buffer layer and the selected side surface have a gap therebetween.

In some embodiments, the buffer layer includes a first slope and a second slope that are connected; in a second direction and a direction pointing from the selected side surface to the second substrate, a height of the first slope gradually increases, and a height of the second slope gradually decreases; and the first slope and the second slope are smoothly connected.

In some embodiments, a slope angle of the first slope and a slope angle of the second slope are each an acute angle.

In some embodiments, the edge portion of the second substrate proximate to the selected side surface is extended with respect to a border of the connection layer proximate to the selected side surface; the edge portion of the second substrate, a side surface of the connection layer and the second surface enclose a gap region; and a portion of the buffer layer fills the gap region.

In another aspect, a display device is provided. The display device includes an integrated circuit chip and the display panel as described in any of the above embodiments, the integrated circuit chip being electrically connected to the second electrodes in the display panel.

In yet another aspect, a tiled display device is provided. The tiled display device includes a plurality of display devices that are tiled as described in any one of the above embodiments.

In yet another aspect, a tiled display device is provided. The tiled display device includes a plurality of display panels that are tiled as described in any one of the above embodiments.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a sectional view showing a structure of a display panel, in accordance with some embodiments;

FIG. 2 is a sectional view showing a structure of a display panel in a manufacturing process, in accordance with some embodiments;

FIG. 3 is a structural diagram of a side of a first surface of a display panel, in accordance with some embodiments;

FIG. 4 is a structural diagram of a side of a second surface of a display panel, in accordance with some embodiments;

FIG. 5 is a sectional view showing a structure of the display panel in FIG. 4 taken along the section line AA, in accordance with some embodiments;

FIG. 6 is an enlarged view showing a structure of the region B of the display panel in FIG. 5;

FIG. 7 is an enlarged view showing another structure of the region B of the display panel in FIG. 5;

FIG. 8 is a structural diagram of a connection layer, in accordance with some embodiments;

FIG. 9 is a structural diagram of a connection layer, in accordance with some other embodiments;

FIG. 10 is a structural diagram of a connection layer, in accordance with yet some other embodiments;

FIG. 11 is a structural diagram of a connection layer, in accordance with still some other embodiments;

FIG. 12 is a structural diagram of a connection layer, in accordance with yet some other embodiments;

FIG. 13 is a structural diagram of a connection layer, in accordance with yet some other embodiments;

FIG. 14 is a structural diagram of a second substrate, in accordance with some embodiments;

FIG. 15 is a structural diagram of a second substrate, in accordance with some other embodiments;

FIG. 16 is a structural diagram of a second substrate, in accordance with yet some other embodiments;

FIG. 17 is a sectional view showing a structure of the display panel in FIG. 15 taken along the section line CC, in accordance with some embodiments;

FIG. 18 is a structural diagram of a side of a second surface of a display panel, in accordance with some embodiments;

FIG. 19 is a structural diagram of a side of a second surface of a display panel, in accordance with some other embodiments;

FIG. 20 is a structural diagram of a display device, in accordance with some embodiments; and

FIG. 21 is a structural diagram of a tiled display device, in accordance with some embodiments.

### DETAILED DESCRIPTION

The technical solutions in embodiments of the present disclosure will be described clearly and completely with reference to the accompanying drawings. However, the described embodiments are merely some but not all of embodiments of the present disclosure. All other embodiments obtained on the basis of the embodiments of the present disclosure by a person of ordinary skill in the art shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, specific features, structures, materials, or characteristics described herein may be included in any one or more embodiments or examples in any suitable manner.

Hereinafter, the terms “first” and “second” are only used for descriptive purposes, and are not to be construed as indicating or implying the relative importance or implicitly indicating the number of indicated technical features. Thus, features defined with “first” and “second” may explicitly or implicitly include one or more of the features. In the description of the embodiments of the present disclosure, the terms “a plurality of” “the plurality of” and “multiple” each mean two or more unless otherwise specified.

In the description of some embodiments, terms such as “coupled” and “connected” and their derivatives may be used. The term “connected” should be understood in a broad sense. For example, the term “connected” may represent a fixed connection, or a detachable connection, or a one-piece connection; alternatively, the term “connected” may represent a direct connection, or an indirect connection through an intermediate medium. The term “coupled”, for example, indicates that two or more components are in direct physical or electrical contact. The term “coupled” or “communicatively coupled” may also indicate that two or more components are not in direct contact with each other, but still cooperate or interact with each other. The embodiments disclosed herein are not necessarily limited to the content herein.

The phrase “at least one of A, B and C” has the same meaning as the phrase “at least one of A, B or C”, both including following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

The phrase “applicable to” or “configured to” used herein means an open and inclusive expression, which does not exclude devices that are applicable to or configured to perform additional tasks or steps.

In addition, the use of the phrase “based on” or “according to” is meant to be open and inclusive, since a process, step, calculation or other action that is “based on” or “according to” one or more of the stated conditions or values may, in practice, be based on or according to additional conditions or values exceeding those stated.

The term such as “about”, “substantially” or “approximately” as used herein includes a stated value and an average value within an acceptable range of deviation of a particular value, and the acceptable range of deviation is determined by a person of ordinary skill in the art in view of the measurement in question and errors associated with measurement of a particular quantity (i.e., the limitation of the measurement system).

The term such as “parallel”, “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Variations in shape relative to the accompanying drawings due to, for example, manufacturing technologies and/or tolerances may be envisaged. Therefore, the exemplary embodiments should not be construed as being limited to the shapes of the regions shown herein, but including deviations due to, for example, manufacturing. For example, an etched region shown in a rectangular shape generally has a feature of being curved. Therefore, the regions shown in the accompanying drawings are schematic in nature, and their shapes are not intended to show actual shapes of the region in a device, and are not intended to limit the scope of the exemplary embodiments.

A display panel, display device and tiled display device provided in the present disclosure will be introduced below.

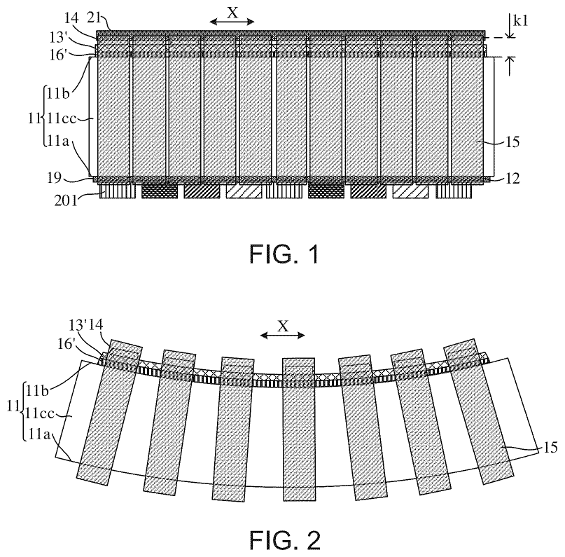

In the present disclosure, FIG. 1 is a sectional view showing a structure of a display panel according to some embodiments. In order to clearly describe change in a structure of the display panel during a manufacturing process, first electrodes 12, light-emitting devices 201, and other structures in the display panel are not shown in FIG. 2 to obtain a sectional view in FIG. 2 showing a structure that only includes a first substrate 11, an electrode carrying plate 13′, second electrodes 14, a bonding adhesive 16′ and connection leads 15.

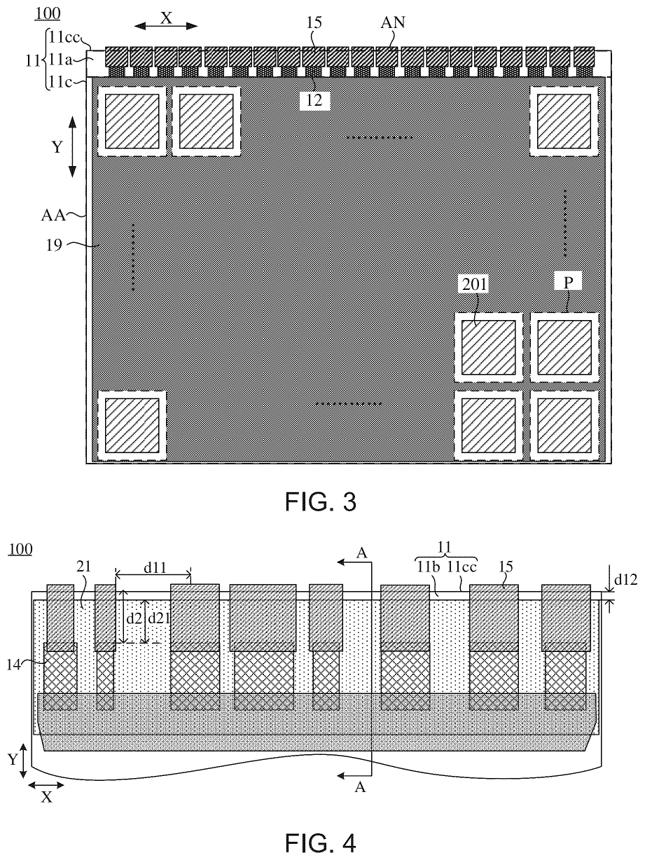

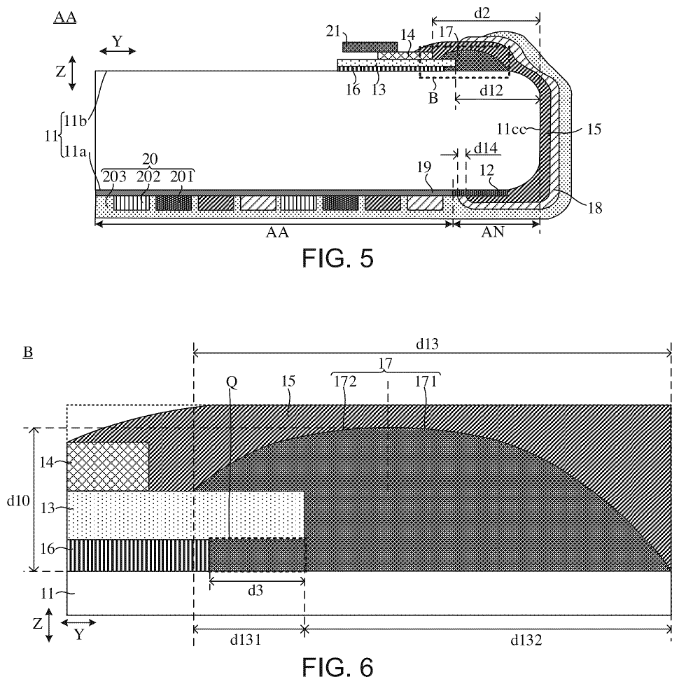

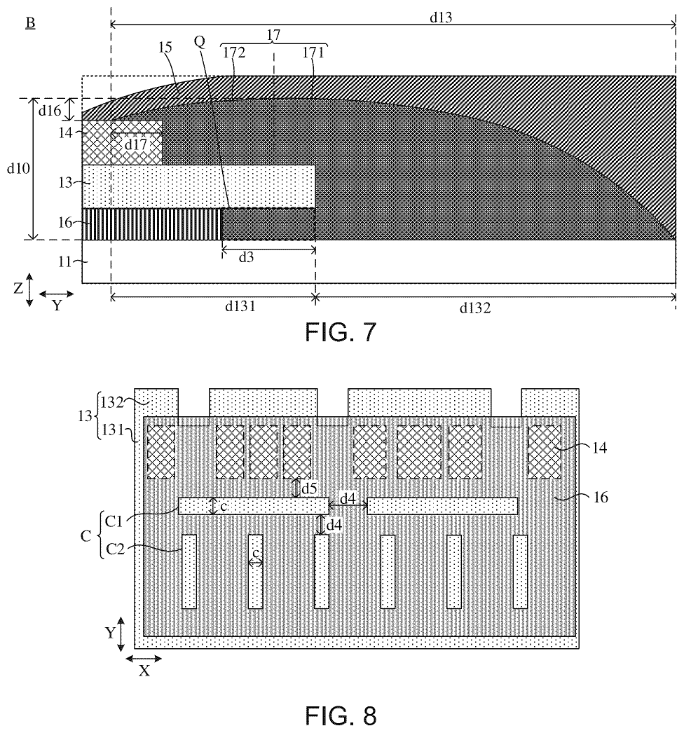

FIGS. 3, 4, 18 and 19 are each a plan view showing a structure of the display panel 100 according to some other embodiments. FIG. 5 is a sectional view of the display panel 100 in FIG. 4 taken along the section line AA. FIGS. 6 and 7 are enlarged views of the region B of the display panel shown in FIG. 5.

The second electrodes 14 and the connection layer 16 are disposed on two opposite sides of the second substrate 13. In order to clearly describe the arrangement of grooves C in the connection layer 16, the second electrodes 14 and the connection layer 16 are arranged on one side of the second substrate 13 to obtain structural diagrams of the connection layer in FIGS. 8 to 13. FIGS. 14 to 16 are structural diagrams of the second substrate.

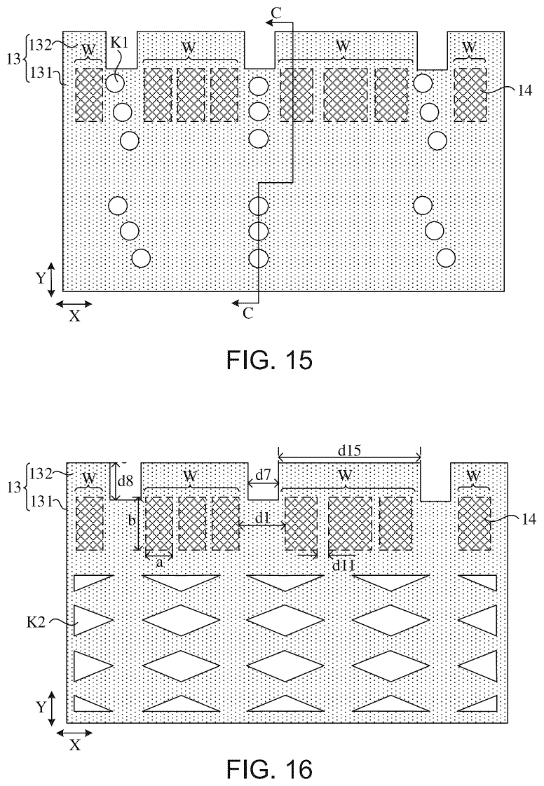

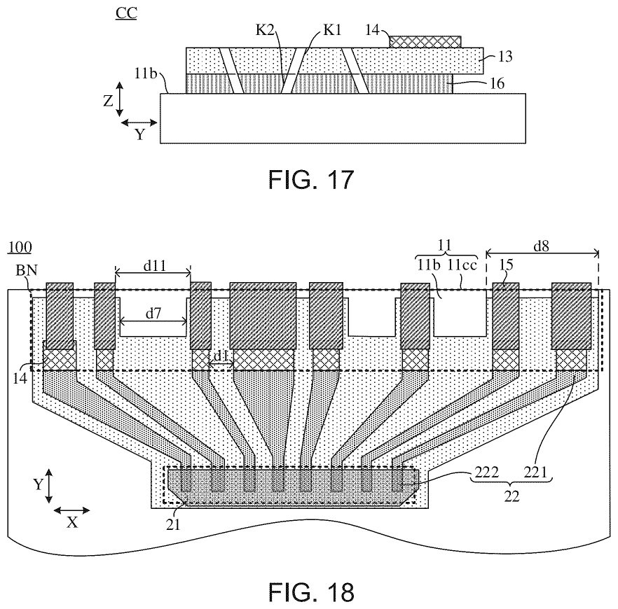

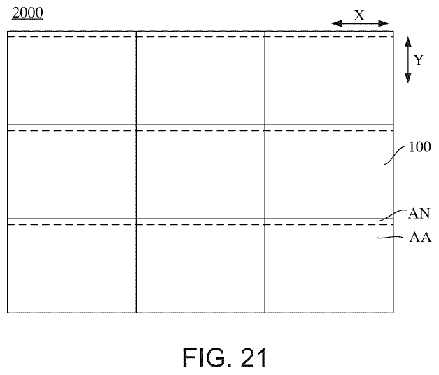

FIG. 17 is a sectional view showing a structure of the display panel 100 in FIG. 15 taken along the section line CC according to some embodiments. In order to clearly describe the corresponding relationship between a second via hole K2 in the connection layer 16 and a first via hole K1 in the second substrate 13, the first electrodes 12, the connection leads 15 and other structures in the display panel 100 are not shown in the figure. FIG. 20 is a plan view showing a structure of the display device 1000 according to some embodiments. FIG. 21 is a plan view showing a structure of the tiled display device 2000 according to some embodiments.

In some embodiments, as shown in FIG. 1, the display panel 100 includes: a first substrate 11, a driving circuit layer 19, a plurality of light-emitting devices 201, a plurality of first electrodes 12, an electrode carrying plate 13′, a plurality of second electrodes 14 and a plurality of connection leads 15. The first substrate 11 includes a first surface 11a and a second surface 11b that are opposite to each other, and a plurality of side surfaces 11c connecting the first surface 11a and the second surface 11b. At least one side surface 11c is a selected side surface 11cc. The driving circuit layer 19, the light-emitting devices 201 and the first electrodes 12 are disposed on the first surface 11a. The driving circuit layer 19 is electrically connected to the first electrodes 12 and the light-emitting devices 201. The electrode carrying plate 13′ is disposed on the second surface 11b of the first substrate 11. The second electrodes 14 are disposed on a side of the electrode carrying plate 13′ away from the first substrate 11. An end of the connection lead 15 is connected to the first electrode 12, and another end of the connection lead 15 extends from the first surface 11a through the selected side surface 11cc to the second surface 11b to be connected to the second electrode 14.

For example, a thickness of the first substrate 11 may be in a range of 0.1 mm to 1 mm.

For example, each first electrode 12 is arranged opposite to a single second electrode 14 in a direction perpendicular to the first surface 11a of the first substrate 11. An orthographic projection of each first electrode 12 on the first surface 11a overlaps or substantially overlaps an orthographic projection of a single second electrode 14 on the first surface 11a.

For example, as shown in FIG. 1, the display panel 100 further includes a driving circuit board 21 disposed on a side of the second electrodes 14 away from the first substrate 11. The driving circuit board 21 is configured to output driving signals (such as display driving signals). The driving signal is sequentially transmitted to the driving circuit layer 19 passing through the second electrode 14, the connection lead 15 and the first electrode 12. The driving circuit layer 19 transmits the driving signal to the light-emitting device 201 to control the light-emitting device 201 to emit light, so that the display panel 100 displays images.

For example, the driving circuit layer 19 includes a plurality of signal lines and a plurality of pads, and the pads are electrically connected to the signal lines. For example, each signal line is connected to a single first electrode 12, and a pin of the light-emitting device 201 is connected to a pad.

In some examples, the electrode carrying plate 13′ is bonded to the first substrate 11 through a bonding adhesive 16′; the electrode carrying plate 13′ and the bonding adhesive 16′ have approximately the same size; and a surface of the electrode carrying plate 13′ proximate to the first substrate 11 is completely covered by the bonding adhesive 16′. When the ambient temperature changes, the bonding adhesive 16′ will undergo expansion or contraction deformation under the influence of the ambient temperature. The deformation of the bonding adhesive 16′ due to the influence of the temperature is related to the variation in the ambient temperature.

For example, in the manufacturing process of the display panel, a die bonding process is performed after the connection leads 15 are formed. The plurality of light-emitting devices 201 are fixed to the first substrate 11 through the die bonding process. In the die bonding process, for example, pins of the plurality of light-emitting devices 201 are soldered to the pads through a soldering process. In the soldering process, the ambient temperature (ambient temperature of the bonding adhesive 16′), for example, increases from the room temperature (20±5° C.) to be in a range of 150° C. to 380° C., and then gradually decreases to the room temperature. The ambient temperature changes greatly in this process. Borders, proximate to the selected side surface 11cc, of the electrode carrying plate 13′ and the bonding adhesive 16′ are approximately flush. During the change process of the ambient temperature, the bonding adhesive 16′ undergoes thermal expansion in a rising phase of the ambient temperature, and then the bonding adhesive 16′ gradually contracts in a dropping phase of the ambient temperature. During the expansion or contraction deformation process of the bonding adhesive 16′ under the influence of the temperature, a distance between second electrodes 14 may increase or decrease. A portion of the connection lead 15 located on the second surface 11b is connected to the second electrode 14; therefore, during this process, the connection lead 15 is subjected to tensile force and/or shear force, and is prone to be broken.

In addition, since the first substrate 11 has a small thickness, when the adhesive 16′ undergoes expansion or contraction deformation under the influence of the ambient temperature, it will also cause the first substrate 11 to undergo warpage deformation. For example, as shown in FIG. 2, the bonding adhesive 16′ undergoes contraction deformation, causing the first substrate 11 to undergo warpage deformation. In this case, the second surface 11b of the first substrate 11 where the bonding adhesive 16′ is disposed changes from a flat surface to a warp surface that protrudes toward the first surface 11a; the warpage of the first substrate 11 is, for example, greater than 0.1 mm; and the connection leads 15 are subjected to shear force in a first direction X and tensile force in a second direction Y, resulting in a risk of breakage.

In light of this, the embodiments of the present disclosure provide a display panel 100. As shown in FIGS. 3, 4 and 5, the display panel 100 includes a first substrate 11, a plurality of first electrodes 12, a second substrate 13, a plurality of second electrodes 14, a plurality of connection leads 15 and a connection layer 16.

As shown in FIG. 3, the first surface 11a includes a display region AA and a peripheral region AN located on at least one side of the display region AA. The peripheral region AN is closer to the selected side surface 11cc than the display region AA. The plurality of first electrodes 12 are arranged in the peripheral region AN at intervals in the first direction X. As shown in FIGS. 4 and 5, the second substrate 13 is disposed on the second surface 11b, and the plurality of second electrodes 14 are disposed on a side of the second substrate 13 away from the first substrate 11. The first direction X is parallel to the second surface 11b and the selected side surface 11cc of the first substrate 11.

As shown in FIG. 5, the connection lead 15 extends from the first surface 11a to the second surface 11b through the selected side surface 11cc. An end of the connection lead 15 is connected to the first electrode 12, and another end of the connection lead 15 is connected to the second electrode 14. The connection layer 16 is disposed between the first substrate 11 and the second substrate 13. The connection layer 16 bonds the first substrate 11 to the second substrate 13. An orthogonal projection of the connection layer 16 on the second surface 11b is located within an orthogonal projection of the second substrate 13 on the second surface 11b.

As shown in FIG. 2, the connection layer 16 may undergo expansion or contraction deformation under the influence of the temperature. The deformation of the connection layer 16 in the first direction X and the second direction Y will cause the connection lead to be subjected to a stress. For example, the deformation of the connection layer 16 in the first direction X may cause the portion of the connection lead 15 that is connected to the second electrode 14 to be subjected to shear force, and the deformation of the connection layer 16 in the second direction Y may cause the portion of the connection lead 15 that is connected to the second electrode 14 to be subjected to tensile force, resulting in a risk of disconnection of the connection lead 15.

By reducing the area of the connection layer 16, the connection layer 16 covers only a part of a surface of the second substrate 13 proximate to the first substrate 11. Compared to a design in which the connection layer 16 completely covers the surface of the second substrate 13, the contact area between the connection layer 16 and the second substrate 13 is reduced and the contact area between the connection layer 16 and the first substrate 11 is reduced, so that when the connection layer 16 undergoes the expansion or contraction deformation under the influence of the ambient temperature, the deformation amount of the connection layer 16 is smaller. Therefore, the shear force and/or tensile force on the connection lead 15 is reduced, which avoids the breakage of the connection lead 15 due to the stress generated by the connection layer 16 during deformation, and in turn ensures the reliability of the connection lead 15. As a result, the driving signal can be transmitted to the light-emitting device 201 through the connection lead 15 to ensure that the display panel 100 can normally display images.

Moreover, since the contact area between the connection layer 16 and the second substrate 13 is reduced and the contact area between the connection layer 16 and the first substrate 11 is reduced, when the connection layer 16 undergoes the expansion or contraction deformation, the warpage deformation amount of the first substrate 11 is also decreased. Therefore, in the manufacturing process of the display panel 100, the first surface 11a and the second surface 11b of the first substrate 11 can be maintained as flat surfaces (whose curvature is less than 0.1 mm, maintained as flat surfaces or approximately as flat surfaces), which avoids the breakage of the connection lead 15 subjected to the stress due to the warpage deformation of the first substrate 11, and in turn ensures the reliability of the connection lead 15. As a result, the driving signal can be transmitted to the light-emitting device 201 through the connection lead 15 to ensure that the display panel 100 can normally display images.

In some embodiments, a material of the connection layer 16 includes, but is not limited to, at least one of thermoset adhesive, pressure sensitive adhesive, or reticulate adhesive.

For example, the coefficient of thermal expansion of the material of the connection layer 16 is less than or equal to 20 PPM/° C.

In some embodiments of the present disclosure, the coefficient of thermal expansion of the material of the connection layer 16 needs to be ensured to be within a set range, so that the connection layer 16 has less deformation when it expands or contracts under the influence of the ambient temperature. Therefore, the deformation of the connection layer 16 causes little change in the relative position of the second substrate 13 to the selected side surface of the first substrate 11, which reduces the force on the connection leads 15 when the connection layer 16 is deformed, and in turn avoid the breakage problem of the connection leads 15. As a result, the reliability of the connection leads 15 is ensured; and the driving signals can be transmitted to the light-emitting devices 201 through the connection leads 15, which ensures the normal display of the display panel 100.

Referring to FIGS. 4 and 5, in the second direction Y, a distance between a border of the second electrode 14 proximate to the selected side surface 11cc and the selected side surface 11cc is d2.

In some embodiments, d2 is less than or equal to 1.6 mm and greater than or equal to 1 mm (1.6 mm≥d2≥1 mm). Since the second substrate 13 and the connection layer 16 are disposed between the second electrode 14 and the first substrate 11, the distance between the second electrode 14 and the first substrate 11 is large. A distance between a part, located on the second substrate 13, of a portion of the connection lead 15 that is located on the second surface 11b and the first substrate 11 is different from a distance between a part, proximate to the selected side surface 11cc, of the portion of the connection lead 15 that is located on the second surface 11b and the first substrate 11. A part, on the second substrate 13 and proximate to the selected side surface 11cc, of a portion of the connection lead 15 that is connected to the second electrode 14 is subjected to significance force, resulting in a risk of the portion of the connection lead 15 located on the second substrate 13 being detached from the first substrate 11.

For example, when the connection layer 16 is made of an adhesive material, bubbles may exist between the second substrate 13 and the first substrate 11 due to problems such as uneven attachment of the adhesive material. The bubbles may exist between the first substrate 11 and the connection layer 16, or exist between the connection layer 16 and the second substrate 13. Under the influence of the ambient temperature, when the adhesive material undergoes expansion or contraction deformation, bubbles may also be created in the adhesive material. When the bubbles between the second substrate 13 and the first substrate 13 overflow toward the selected side surface 11cc, bubbles will exist between the portion of the connection lead 15 proximate to the selected side surface 11cc and the second surface 11b of the first substrate 11, reducing the connection stability of the connection lead 15, resulting in a risk of the connection lead 15 being detached from the first substrate 11, and a risk of disconnection between the second electrode 14 and the connection lead 15.

In some other embodiments, as shown in FIGS. 4 and 5, the border of the second electrode 14 proximate to the selected side surface 11cc is farther away from the selected side surface 11cc than the border of the second substrate 13 proximate to the selected side surface 11cc. In the second direction Y, the distance d21 between the border of the second electrode 14 proximate to the selected side surface 11cc and the border of the second substrate 13 proximate to the selected side surface 11cc is less than or equal to 0.5 mm and greater than or equal to 0.1 mm (0.5 mm≥d21≥0.1 mm).

For example, as shown in FIGS. 4 and 5, an end of the connection lead 15 and an end of the second electrode 14 that are proximate to each other are connected or overlap.

When the connection lead 15 and the second electrode 14 overlap, a contact area of the connection lead 15 and the second electrode 14 is increased, and the risk of disconnection between the connection lead 15 and the second electrode 14 is reduced, so that the connection stability of the connection lead 15 and the second electrode 14 is increased. When a portion of the connection lead 15 and a portion of the second electrode 14 that overlap have the same size in the second direction Y, by increasing the distance d21 between the border of the second electrode 14 proximate to the selected side surface 11cc and the border of the second substrate 13 proximate to the selected side surface 11cc, the size of the portion of the connection lead 15 located on the second substrate 13 is increased, the contact area between the connection lead 15 and the second substrate 13 is increased, which makes the connection lead 15 more tightly bonded to the second substrate 13, thereby reducing the risk of the connection lead 15 being detached from the second substrate 13, increasing the connection stability between the connection lead 15 and the second electrode 14, and in turn ensuring the reliability of the connection lead 15. As a result, the driving signal can be transmitted to the light-emitting device 201 through the connection lead 15 to ensure that the display panel 100 can display images normally.

The distance between the border of the second electrode 14 proximate to the selected side surface 11cc and the border of the second substrate 13 proximate to the selected side surface 11cc is d21, which may be selected according to the design requirements. The description here is for illustrative purposes only and is not intended to limit the present disclosure.

For example, the plurality of the first electrodes 12 are arranged at intervals in the first direction X, and each first electrode 12 extends in the second direction Y Sizes of the plurality of first electrodes 12 in the first direction X are the same or not necessarily the same, and sizes of the plurality of first electrodes 12 in the second direction Y are the same.

For example, a distance between any two adjacent first electrodes 12 is the same or not necessarily the same.

By controlling the distance between adjacent first electrodes 12, during the process of forming the connection leads 15, it is possible to ensure the effective connection between the connection lead 15 and a corresponding first electrode 12, and prevent the connection lead 15 from being in contact with other first electrodes 12 adjacent to the corresponding first electrode 12. Therefore, it avoids a short circuit caused by the same connection lead 15 being electrically connected to two or more first electrodes 12.

In some embodiments, as shown in FIG. 5, the display panel 100 further includes a protective layer 18 covering the plurality of connection leads 15 at least.

For example, a material of the protective layer 18 includes but is not limited to silicon nitride (SiN) or epoxy resin material.

Since the protective layer 18 covers the plurality of connection leads 15, it avoids the problem of water and oxygen corrosion caused by the connection leads 15 being in contact with the air and/or water vapor in the air. The protective layer 18 can also prevent the connection leads 15 from being in contact with other conductive structures in the display panel 100, thereby avoiding the problem of short circuits. Moreover, the protective layer 18 can also protect the connection leads 15 from bumps and damages, which alleviates the problem that the connection leads 15 are partially missing or broken due to bumps of the connection leads 15, and in turn ensures the reliability of the connection leads 15. Therefore, the driving signal can be transmitted to the light-emitting device 201 through the connection lead 15 to ensure that the display panel 100 can display images normally.

For example, a deposition process or a printing process is used to form the protective layer 18 on a side of the connection leads 15 away from the first substrate 11. The protective layer 18 covers the plurality of connection leads 15 to avoid water and oxygen corrosion caused by the connection leads 15 being in contact with the air and/or water vapor in the air.

For example, as shown in FIG. 5, the plurality of connection leads 15 are covered by the protective layer 18. A distance between an outermost border of the plurality of connection leads 15 and a border of the protective layer 18 is d14, and d14 is less than or equal to 22 μm and greater than or equal to 18 μm (22 μm≥d14≥18 μm).

For example, as shown in FIG. 5, the protective layer 18 further covers portions of the plurality of second electrodes 14 proximate to the selected side surface 11cc; or the protective layer 18 completely covers the plurality of second electrodes 14.

For example, as shown in FIG. 5, the protective layer 18 covers portions of the plurality of first electrodes 12 proximate to the selected side surface 11cc at least; or the protective layer 18 completely covers the plurality of first electrodes 12.

The protective layer 18 covers portions of the first electrodes 12 and the second electrodes 14 that do not need to be connected to other structures, thereby avoiding water and oxygen corrosion caused by the connection leads 15 being in contact with the air and/or water vapor in the air. The protective layer 18 can also prevent the first electrodes 12 and the second electrodes 14 from being in contact with other conductive structures in the display panel 100, thereby avoiding short circuits. In addition, the protective layer 18 can also protect the first electrodes 12 and the second electrodes 14 from bumps and damages, which alleviates the first electrodes 12 and the second electrodes 14 are partially missing or broken due to the bumps of the first electrodes 12 and the second electrodes 14, and in turn ensures the reliability of the first electrodes 12 and the second electrodes 14. Therefore, the driving signal can be transmitted to the light-emitting device 201 by passing through the second electrode 14, the connection lead 15 and the first electrode 12 in sequence, which ensures that the display panel 100 can display images normally.

In some embodiments, as shown in FIG. 5, the display panel 100 further includes a buffer layer 17 disposed on the side of the second substrate 13 away from the first substrate 11. The buffer layer 17 covers an edge portion of the second substrate 13 proximate to the selected side surface 11cc. The connection lead 15 is connected to the second electrode 14 across the buffer layer 17.

By providing the buffer layer 17, the adhesion tightness between the portion of the second substrate 13 proximate to the selected side surface 11cc and the first substrate 11 is increased, which avoids the deviation of the second electrode 14 from a set position due to the shifting of the second substrate 13, and in turn ensures that the connection lead 15 and the second electrode 14 can be effectively connected. Therefore, the driving signal can be transmitted to the light-emitting device 201 through the connection lead 15 to ensure that the display panel 100 can display images normally.

For example, the second substrate 13 undergoes expansion and contraction deformations under the influence of temperature, and the buffer layer 17 fixes the side of the second substrate 13 proximate to the selected side surface 11cc. Since the second electrode 14 is located close to the selected side surface 11cc, it can be understood that the second electrode 14 can still be ensured to be at the set position without deviation when undergoing expansion and contraction deformations on the second substrate 13, which ensures that the connection lead 15 can be effectively connected to the second electrode 14.

In some examples, as shown in FIG. 1, the distance k1 between the surface of the second electrode 14 away from the first substrate 11 and the first substrate 11 is greater than the thickness of the connection lead 15, and there is an obvious step difference between the second electrode 14 and the first substrate 11. Therefore, when the connection lead 15 extends from the second surface 11b of the first substrate 11 to the second substrate 13 to be connected to the second electrode 14, the breakage problem is prone to occur at the position of the step difference, causing an abnormal transmission of the driving signal.

For example, a material of the buffer layer 17 includes but is not limited to a reinforced adhesive.

For example, the coefficient of thermal expansion of the material of the buffer layer 17 is less than or equal to 20 PPM/° C.

The coefficient of thermal expansion of the material of the buffer layer 17 needs to be ensured to be within a set range, so that the deformation of the buffer layer 17 when it expands or contracts under the influence of the ambient temperature is small, which avoids the deviation of the second electrode 14 from the set position caused by the shifting of the second substrate 13 due to the expansion and contraction deformations of the buffer layer 17, and in turn ensures that the connection lead 15 can be effectively connected to the second electrode 14.

For example, after the attachment of the second substrate 13 is completed, a printing process is used to print reinforced adhesive on the edge portion of the second substrate 13 proximate to the selected side surface 11cc to fill the step difference location, so as to ameliorate the step difference of the connection lead 15 extending from the second surface 11b to the surface of the second substrate 13, and in turn prevent the problem that the driving signal cannot be transmitted normally due to the breakage of the connection lead 15.

In some embodiments, a thickness of the second electrode 14 is less than 5 μm. As shown in FIG. 6, the buffer layer 17 does not overlap the second electrodes 14.

In some other embodiments, the thickness of the second electrode 14 is greater than or equal to 5 μm. As shown in FIG. 7, the buffer layer 17 further covers edge portions of the second electrodes 14 proximate to the selected side surface 11cc.

Since the border of the buffer layer 17 away from the selected side surface 11cc is arranged on the second electrodes 14, the buffer layer 17 overlaps the second electrodes 14. In this way, the step difference location between the side of the second electrode 14 proximate to the selected side surface 11cc and the second substrate 13 is filled, which alleviates the step difference of the connection lead 15 extending from the second substrate 13 to the surface of the second electrode 14, which in turn avoids the abnormal transmission problem of the driving signal caused by the breakage of the connection lead 15.

For example, as shown in FIG. 7, in the second direction Y, a size d17 of an overlapping portion of the buffer layer 17 and the second electrode 14 is less than or equal to 100 μm.

In some embodiments, as shown in FIGS. 6 and 7, the buffer layer 17 includes a first slope surface 171 and a second slope surface 172 that are connected to each other. In the second direction Y and in a direction pointing from the selected side surface 11cc to the second substrate 13, a height of the first slope surface 171 gradually increases, and a height of the second slope surface 172 gradually decreases. The first slope surface 171 is smoothly connected to the second slope surface 172.

The first slope surface 171 is closer to the selected side surface 11cc than the second slope surface 172. The connection leads 15 are, for example, disposed on a side of the buffer layer 17 away from the first substrate 11. A distance between a portion of the connection lead 15 located on the second surface 11b of the first substrate 11 and the first substrate 11 in a third direction Z gradually increases in a direction from the selected side surface 11cc toward the second electrode 14. The third direction Z is perpendicular to the second surface 11b of the first substrate 11 and parallel to the selected side surface 11cc. For example, the height of the first slope surface 171 is a distance between the first slope surface 171 and the first substrate 11 in the third direction Z, and the height of the second slope surface 172 is a distance between the second slope surface 172 and the first substrate 11 in the third direction Z.

Compared with the case where the portion of the connection lead 15 located on the second surface 11b is connected to the second electrode 14 across the portion of the second substrate 13 proximate to the selected side surface 11cc, in the embodiments of the present disclosure, it reduces the change range of the distance between the connection lead 15 and the first substrate 11 in the third direction Z, avoids the breakage problem of the connection lead 15 due to a large step difference, ensures the reliability of the connection lead 15, and ensures the effective connection between the second electrode 14 and the connection lead 15. As a result, the driving signal can be transmitted to the light-emitting device 201 through the connection lead 15 to ensure that the display panel 100 can display images normally.

For example, as shown in FIG. 5, a surface of the buffer layer 17 away from the first substrate 11 is arched in a direction away from the first substrate 11 to be in a hill-like shape.

In some embodiments, as shown in FIGS. 6 and 7, a slope angle of the first slope surface 171 and a slope angle of the second slope surface 172 are each an acute angle.

In this way, the distance between the portion of the connection lead 15 that extends from the second surface 11b of the first substrate 11 to onto the second substrate 13 and is connected to the second electrode 14 and the first substrate 11 gradually increases. The slower the distance increases, the more likely the connection lead 15 is to be arranged on a plane. Therefore, the slope angle of the first slope 171 and the slope angle of the second slope 172 are set to acute angles, which ensures that the connection lead 15 can be approximately arranged on a plane, and in turn reduces the risk of breakage of the connection lead 15 and ensures the effective connection between the second electrode 14 and the connection lead 15. As a result, the driving signal can be transmitted to the light-emitting device 201 through the connection lead 15 to ensure that the display panel 100 can display images normally.

For example, as shown in FIGS. 6 and 7, an angle between a tangent plane, at any point on the first slope surface 171 and the second slope surface 172, and the second surface 11b is α, and 50°≥α≥30°.

In some embodiments, as shown in FIGS. 6 and 7, an edge portion of the second substrate 13 proximate to the selected side surface 11cc is extended with respect to a border of the connection layer 16 proximate to the selected side surface 11cc. The edge portion of the second substrate 13, the side surface 11c of the connection layer 16, and the second surface 11b enclose a gap region Q, and a portion of the buffer layer 17 fills the gap region Q.

The buffer layer 17 also connects the second substrate 13 and the first substrate 11 while filling the gap region Q between the portion of the second substrate 13 proximate to the selected side surface 11cc and the first substrate 11. Therefore, it ensures the adhesion tightness of the second substrate 13 and the first substrate 11, avoids the warp of the edge portion of the second substrate 13, and in turn reduces the risk of breakage of the connection lead 15 caused by the warp portion of the second substrate 13 when the edge portion of the second substrate 13 warps. As a result, the driving signal can be transmitted to the light-emitting device 201 through the connection lead 15 to ensure that the display panel 100 can display images normally.

For example, as shown in FIGS. 6 and 7, in the third direction Z, a distance between the buffer layer 17 and the first substrate 11 is d10, and 120 μm≥d10≥0 μm.

In some examples, as shown in FIG. 7, the buffer layer 17 covers the edge portion of the second electrode 14 proximate to the selected side surface 11cc; in the third direction Z, a distance between the buffer layer 17 and the second electrode 14 is d16, and 20 μm≥d16≥0 μm.

In some embodiments, as shown in FIG. 5, the buffer layer 17 and the selected side surface 11cc have a gap therebetween.

It can be understood that a border of the buffer layer 17 proximate to the selected side surface 11cc and the selected side surface 11cc may have a certain spacing therebetween, or may overlap, or may substantially overlap.

In some embodiments, as shown in FIG. 5, in the second direction Y, a distance between the second substrate 13 and the selected side surface 11cc is d12. For example, 1.1 mm≥d12≥0.9 mm.

It can be understood that compared with a design in which the border of the second substrate 13 proximate to the selected side surface 11cc overlaps or substantially overlaps the selected side surface 11cc, by controlling the distance between the second substrate 13 and the selected side surface 11cc, the space for arranging the buffer layer 17 is reserved, and the length of the portion of the connection lead 15 located between the second substrate 13 and the selected side surface 11cc is extended. By providing the buffer layer 17, the connection lead 15 can be approximately arranged on a plane, thereby reducing the risk of breakage of the connection lead 15 under the influence of the step difference between the second electrode 14 and the first substrate 11.

For example, as shown in FIGS. 6 and 7, a size of the buffer layer 17 in the second direction Y is d13, and d13≥0.6 mm.

For example, as shown in FIGS. 6 and 7, in the second direction Y, a distance between a border of the buffer layer 17 away from the selected side surface 11cc and a border of the second substrate 13 proximate to the selected side surface 11cc is d131, and 0.3 mm≥d131≥0.2 mm.

For example, as shown in FIGS. 6 and 7, in the second direction Y, a distance between the border of the buffer layer 17 proximate to the selected side surface 11cc and the border of the second substrate 13 proximate to the selected side surface 11cc is d132, and 0.3 mm≥d132≥0.2 mm.

Referring to FIGS. 6 and 7, a distance between the border of the connection layer 16 proximate to the selected side surface 11cc and the border of the second substrate 13 proximate to the selected side surface 11cc is d3.

In the display panel shown in FIG. 1, the surface of the second electrode 14 away from the first substrate 11 and the first substrate 11 have a large distance therebetween, and the distance k1 is, for example, 100 μm. Therefore, a portion of the second electrode 14 proximate to the selected side surface 11cc has a large step difference, and a part of the connection lead 15 located at the position of step difference is subject to great force. When the first substrate 11 warps or when the electrode carrying plate 1′ and the first substrate 11 move relative to each other, the connection lead 15 is prone to be broken, causing in an open circuit in the display panel. As a result, the electrical signal cannot be transmitted normally, and the display panel cannot display images normally.

In some embodiments, as shown in FIGS. 6 and 7, compared to the border of the second substrate 13 proximate to the selected side surface 11cc, the border of the connection layer 16 proximate to the selected side surface 11cc is farther away from the selected side surface 11cc; alternatively, the border of the connection layer 16 proximate to the selected side surface 11cc overlaps or substantially overlaps the border of the second substrate 13 proximate to the selected side surface 11cc.

For example, 0.3 mm≥d3>0 mm.

By using the design shown in FIGS. 6 and 7, a distance between portions of the second substrate 13 and the first substrate 11 that no connection layer 16 is interposed is less than a distance between portions of the second substrate 13 and the first substrate 11 that the connection layer 16 is interposed. In this way, when the second substrate 13 is attached to the second surface 11b of the first substrate 11, while ensuring that the second substrate 13 is effectively attached, the distance a portion of the connection lead 15 located on the border of the second substrate 13 proximate to the selected side surface 11cc and the first substrate 11 gradually increases in a direction gradually moving away from the selected side surface 11cc. Compared with the design shown in FIG. 1, the step difference between the side of the second substrate 13 proximate to the selected side surface 11cc and the first substrate 11 is reduced, which reduces the stress on the connection lead 15 at the step difference, avoids the problem of breakage of the connection lead 15 due to large stress, and ensures the reliability of the connection lead 15. As a result, the driving signal can be transmitted to the light-emitting device 201 through the connection lead 15 to ensure that the display panel 100 can display images normally.

In some embodiments, as shown in FIGS. 8, 9, 10 and 11, the connection layer 16 includes at least one groove C, and the groove(s) C penetrate from an upper surface of the connection layer 16 to a lower surface of the connection layer 16. For example, the upper surface of the connection layer 16 is a surface of the connection layer 16 proximate to the second substrate 13, and the lower surface of the connection layer 16 is a surface of the connection layer 16 proximate to the first substrate 11.

During the manufacturing process of the display panel, for example, during the die-bonding process, a large amount of heat will be generated, causing the connection layer 16 to undergo expansion or contraction deformation under the influence of the ambient temperature. Due to the deformation of the connection layer 16, the relative position of the second substrate 13 and the first substrate 11 will change, which causes change in the relative position of the second electrode 14 and the connection lead 15, resulting in the risk of breakage of the connection lead 15. Moreover, since the connection layer 16 is attached to the surface of the first substrate 11, the expansion and contraction deformation of the connection layer 16 will also cause the warpage deformation of the first substrate 11, which further increases the risk of breakage of the connection lead 15.

By patterning the connection layer 16 to provide the groove(s) C in the connection layer 16, when the ambient temperature changes, the groove(s) C can have the effect of dispersing the stress at high temperature on the connection layer 16, thereby reducing the amount of deformation of the connection layer 16 under the influence of the ambient temperature, and in turn reducing the risk of breakage of the connection leads 15 during the manufacturing process of the display panel. Moreover, since the amount of deformation of the connection layer 16 under the influence of the ambient temperature is reduced, the amount of warpage deformation of the first substrate 11 under the influence of the deformation of the connection layer 16 is also reduced, reducing the risk of breakage of the connection leads 15 during the manufacturing process of the display panel.

When attaching the second substrate 13, bubbles may exist between the connection layer 16 and the first substrate 11 and/or between the connection layer 16 and the second substrate 13 due to problems such as uneven attachment; when the adhesive material undergoes expansion or contraction deformation under the influence of the ambient temperature, bubbles may also be created in the adhesive material; and the bubbles may be discharged through the groove(s) C, thereby ensuring the flatness and tightness of the attachment of the second substrate 13 and the first substrate 11.

It can be understood that the groove C may vertically penetrate from the upper surface of the connection layer 16 to the lower surface of the connection layer 16, or the groove C may obliquely penetrate from the upper surface of the connection layer 16 to the lower surface of the connection layer 16. For example, the groove C penetrates through the connection layer 16 in the third direction Z, and the third direction Z is perpendicular to the first direction X and the second surface 11b. Alternatively, the direction in which the groove C penetrates through the connection layer 16 and the upper surface or lower surface of the connection layer 16 provide an included angle θ, and 90°≥θ>0°.

The description here is for illustrative purposes only and is not intended to limit the present disclosure.

For example, as shown in FIG. 8, a size of the groove C in a direction perpendicular to an extending direction of the groove C is c, and 5 mm≥c≥1 mm.

If the size of the groove C is too large, then too many grooves in the connection layer 16 will cause the area of the connection layer 16 that has the bonding effect to be too small, which will affect the bonding effect of the connection layer 16. If the size of the groove C is too small, when the connection layer 16 undergoes expansion deformation, the groove C may be closed due to the expansion deformation, affecting the effect of the groove C dispersing the stress at high temperature on the connection layer 16. By controlling the width of the groove C, the stress at high temperature on the connection layer 16 is effectively dispersed, and the bonding effect of the connection layer 16 is ensured, so that the second substrate 13 is firmly attached, which avoids the problem of poor connection between the second electrode 14 and the connection lead 15 caused by poor attachment of the second substrate 13.

For example, as shown in FIG. 8, the connection layer 16 includes a plurality grooves C, a distance between any two adjacent grooves C is d4, and d4≥10 mm.

For example, as shown in FIGS. 8, 9, 10, 11, 12 and 13, in the second direction Y, a distance between a groove C closest to a second electrode 14 and the second electrode 14 is d5, and d5≥5 mm.

When attaching the second substrate 13, bubbles may exist between the connection layer 16 and the first substrate 11 and/or between the connection layer 16 and the second substrate 13 due to problems such as uneven attachment; when the adhesive material undergoes expansion or contraction deformation under the influence of the ambient temperature, bubbles may also be created in the adhesive material; and the bubbles may be discharged through the groove(s) C. When the distance between the groove C and the second electrode 14 is too small, the bubbles may overflow to a position between the second electrode 14 and the first substrate 11; and the bubbles further overflow toward the selected side surface 11cc of the first substrate 11, so that bubbles exist between the connection lead 15 and the first substrate 11, which affects the flatness and tightness of the attachment of the connection lead 15 and the first substrate 11.

By controlling the distance between the groove C and the second electrode 14, it prevents bubbles generated when attaching the second substrate 13 from overflowing to the position between the second electrode 14 and the first substrate 11, ensures that the tightness of the attachment of the second substrate 13 and the first substrate 11, avoids a problem of breakage of the connection lead 15 caused by bubbles generated when attaching the second substrate 13 or a problem of poor connection between the second electrode 14 and the connection lead 15, and ensures the reliability of the connection lead 15. As a result, the driving signal can be transmitted to the light-emitting device 201 through the connection lead 15 to ensure that the display panel 100 can display images normally.

In some embodiments, as shown in FIG. 8, the groove C includes: at least one first groove C1, and/or at least one second groove C2; and the first groove C1 and the second groove C2 extend in different directions. A border of the first groove C1 does not overlap the border of the connection layer 16, and a border of the second groove C2 does not overlap the border of the connection layer 16.

By providing the groove(s) C (the first groove C1 and/or the second groove C2) in the connection layer 16, the attaching effect of the second substrate 13 is ensured, and the attaching area of the connection layer 16 is reduced. Thereby, the expansion and contraction deformations of the entire connection layer 16 under the influence of ambient temperature is reduced. Moreover, by providing the first groove C1 and/or the second groove C2 in the connection layer 16, it may be possible to ameliorate the expansion and contraction deformations of the connection layer 16 in a direction perpendicular to the extending direction of the first groove C1 and/or the second groove C2, reduce the amount of deformation of the first substrate 11 caused by the expansion and contraction deformations of the connection layer 16, reduce the risk of breakage of the connection lead 15 caused by the expansion and contraction deformations of the connection layer 16, and ensure the reliability of the connection lead 15. As a result, the driving signal can be transmitted to the light-emitting device 201 through the connection lead 15 to ensure that the display panel 100 can display images normally.

As shown in FIG. 8, the first groove C1 and the second groove C2 are located in the connection layer 16. Therefore, there is no gap at the border of the connection layer 16, so that the edge of the connection layer 16 can be well attached and not easily warp, which effectively avoids a problem that the edge of the connection layer 16 is warped to cause a poor attaching of the second substrate 13. Moreover, the first groove C1 and/or the second groove C2 can also be used as an exhaust channel. When attaching the second substrate 13, bubbles may exist between the connection layer 16 and the first substrate 11 and/or between the connection layer 16 and the second substrate 13 due to problems such as uneven attachment; when the adhesive material undergoes expansion or contraction deformation under the influence of the ambient temperature, bubbles may also be created in the adhesive material; and the bubbles may be discharged through the first groove C1 and the second groove C2. Therefore, it ensures the tightness of attachment of the second substrate 13 and the first substrate 11, avoids poor bonding of the connection leads 15 and the first substrate 11 caused by the bubbles overflowing toward the selected side surface 1cc, prevents the connection lead 15 from being detached from the first substrate 11, reduces the risk of breakage of the connection lead 15, and ensures the reliability of the connection lead 15. As a result, the driving signal can be transmitted to the light-emitting device 201 through the connection lead 15 to ensure that the display panel 100 can display images normally.

For example, as shown in FIG. 8, a size of the groove C in the first direction X is less than a size of the connection layer 16 in the first direction X. A size of the groove C in the second direction Y is less than a size of the connection layer 16 in the second direction Y.

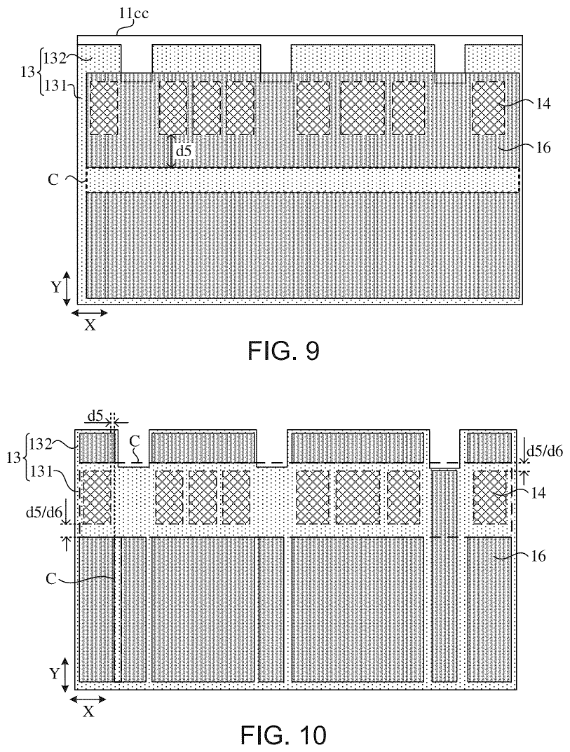

In some embodiments, as shown in FIGS. 9, 10 and 11, the groove C penetrates through the connection layer 16 in a set direction. When the connection layer 16 includes a plurality of grooves C, the plurality of grooves C are arranged at intervals. The set direction is parallel to the upper surface or lower surface of the connection layer 16.

For example, extending directions of the plurality of grooves C are the same or not necessarily the same. When the extending directions of the plurality of grooves C are not necessarily the same, the extending directions of the plurality of grooves C are allowed to intersect.

In some examples, at least two of the plurality of grooves C intersect.

It can be understood that the connection layer 16 may include only one groove C extending in an arbitrary direction, or may include a plurality of grooves C arranged at intervals extending in the same direction, or may include a plurality of grooves C whose extending directions are not necessarily the same. It can be understood that the plurality of grooves may extend in one or more directions.

By providing the groove C extending in the set direction in the connection layer 16, the attaching area of the connection layer 16 is reduced while ensuring the attaching effect of the second substrate 13. Therefore, the expansion and contraction deformations of the entire connection layer 16 under the influence of the ambient temperature is reduced, and the risk of breakage of the connection lead 15 caused by the expansion and contraction deformations of the connection layer 16 is reduced.

Moreover, the groove C can also be used as an exhaust channel. When attaching the second substrate 13, bubbles may exist between the connection layer 16 and the first substrate 11 and/or between the connection layer 16 and the second substrate 13 due to problems such as uneven attachment; when the adhesive material undergoes expansion or contraction deformation under the influence of the ambient temperature, bubbles may also be created in the adhesive material; and the bubbles may be discharged through the groove C. Therefore, it ensures the tightness of attachment of the second substrate 13 and the first substrate 11, avoids poor bonding of the connection leads 15 and the first substrate 11 caused by the bubbles overflowing toward the selected side surface 1cc, prevents the connection lead 15 from being detached from the first substrate 11, reduces the risk of breakage of the connection lead 15, and ensures the reliability of the connection lead 15. As a result, the driving signal can be transmitted to the light-emitting device 201 through the connection lead 15 to ensure that the display panel 100 can display images normally.

For example, the set direction may be parallel to the selected side surface 11cc, or the set direction may be perpendicular to the selected side surface 11cc, or an included angle provided between the set direction and the selected side surface 11cc may be an acute angle.

In some examples, as shown in FIG. 9, the groove(s) C penetrate through the connection layer 16 in the first direction X.

In some other examples, as shown in FIG. 10, part of the grooves C penetrates through the connection layer 16 in the first direction X, and part of the grooves C penetrates through the connection layer 16 in the second direction Y.

A distance between the border of the connection layer 16 and the second electrode 14 in the second direction Y is d6, and d6≥5 mm.

As shown in FIGS. 9 and 10, in the case where the groove(s) C penetrate through the connection layer 16 in the first direction X, the distance d5 between the groove C closest to the second electrode 14 and the second electrode 14 is equal to the distance d6 between the border of the connection layer 16 and the second electrode 14 in the second direction Y.

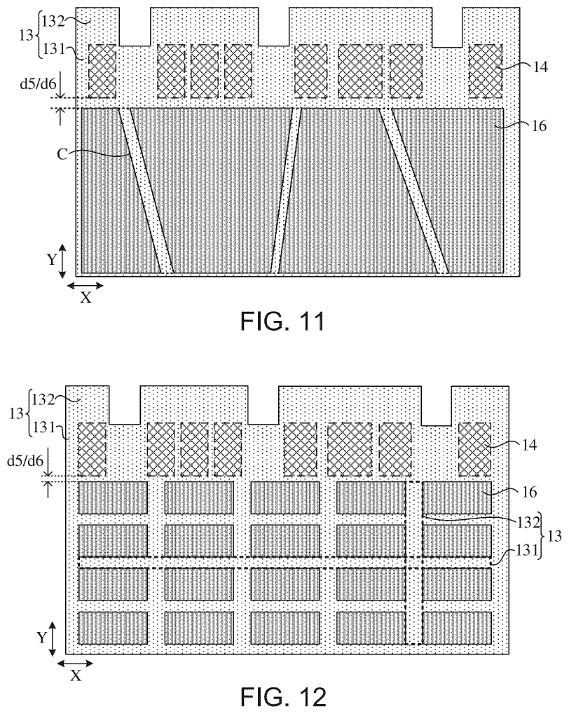

In yet some other examples, as shown in FIG. 11, a plurality of grooves C obliquely penetrate through the connection layer 16, and the plurality of grooves C extend in different directions. An included angle provided by an extending direction of each groove C and the selected side surface 11cc is an acute angle.

In some embodiments, as shown in FIG. 9, in the case where the grooves C penetrate through the connection layer 16 in the first direction X, the groove C is located on a side of the second electrode 14 away from the selected side surface 11cc.

When attaching the second substrate 13, bubbles may exist between the connection layer 16 and the first substrate 11 and/or between the connection layer 16 and the second substrate 13 due to problems such as uneven attachment; and/or, when the adhesive material undergoes expansion or contraction deformation under the influence of the ambient temperature, bubbles are created in the adhesive material; and when the bubbles are discharged through the groove C, the connection layer 16 may be warped at the border of the groove C during the discharge of the bubbles. When the warpage portion is located between the second electrode 14 and the first substrate 11, the second electrode 14 may deviate from the preset position, which causes that the connection lead 15 and the second electrode 14 cannot be effectively connected when forming the connection lead 15, so that the driving signal cannot be transmitted to the light-emitting device 201 normally, and the display panel cannot display images normally.

Since the groove C is disposed on the side of the second electrode 14 away from the selected side surface 11cc, it prevents the warpage of the connection layer 16 at the border of the groove C, and in turn ensures that the connection lead 15 and the second electrode 14 can be effectively connected. Thus, it ensures that the driving signal can be transmitted to the light-emitting device 201 through the connection lead 15, and in turn ensures that the display panel 100 can display images normally.

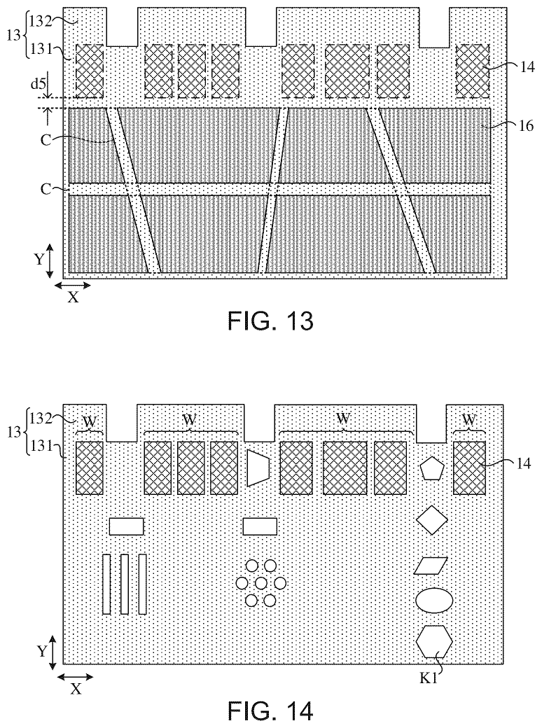

In some embodiments, as shown in FIGS. 12 and 13, there are a plurality of grooves C, and the plurality of grooves C intersect with each other to be of a grid-like structure.

For example, when forming the connection layer 16, for example, a whole mother layer is firstly formed, and then grid-like grooves C are formed in the whole mother layer, thereby obtaining a plurality of blocks arranged in an array; alternatively, when forming the connection layer 16, a plurality of blocks arranged in an array are directly formed. When the connection layer 16 includes a plurality of blocks, shapes of the blocks include but are not limited to at least one of a rectangle, a trapezoid, a triangle, or a parallelogram.

As shown in FIGS. 12 and 13, when the connection layer 16 consists of the plurality of blocks arranged in an array, the plurality of blocks are located on a side of the second electrodes 14 away from the selected side surface 11cc.

For example, a distance between a border of a block closest to the second electrode 14 and the second electrode 14 in the second direction Y is d6, and d6≥5 mm.

In some embodiments, as shown in FIGS. 8 to 16, the second substrate 13 includes a body portion 131 and a plurality of protruding portions 132 disposed on a side of the body portion 131 proximate to the selected side surface 11cc. An end of the protruding portion 132 is connected to the body portion 131, and another end of the protruding portion 132 extends toward the selected side surface 11cc. The plurality of protruding portions 132 are arranged at intervals in the first direction X, the first direction X being parallel to the first surface 11a and the selected side surface 11cc.

In the manufacturing process of the display panel 100, the second substrate 13 is subjected to the influence of the temperature (e.g., high temperature in the die-bonding process), the material of the second substrate 13 undergoes deformation under the influence of the change of the temperature, which drives the second electrode 14 on the second substrate 13 to deviate from the preset position. Therefore, the connection between the connection lead 15 and the second electrode 14 is unreliable, resulting in a risk of disconnection.

By patterning the side of the second substrate 13 proximate to the selected side surface 11cc, a plurality of protruding portions 132 are formed on the side of the second substrate 13 proximate to the selected side surface 11cc. Compared with the design of a border that is parallel to and flush with the entire selected side surface 11cc, an area of the side surface of the second substrate 13 is increased, so that the second substrate 13 can dissipate heat well, and the area of the second substrate 13 is reduced. Thereby, the deformation of the material of the second substrate 13 under the influence of the change of the temperature is reduced, which ensures the reliability of connection between the second electrode 14 and the connection lead 15. Thus, the driving signal can be transmitted to the light-emitting device 201 through the second electrode 14 and the connection lead 15, ensuring that the display panel 100 can display images normally. Moreover, the patterned border of the second substrate 13 can disperse edge stress, which reduces the influence of the change of the ambient temperature on the second substrate 13 and reduces the deformation of the second substrate 13 due to the influence of the temperature, so that the second electrode 14 on the second substrate 13 can be maintained at the set position without deviation. Therefore, the connection lead 15 and the second electrode 14 can be effectively connected, which ensures that the driving signal can be transmitted to the light-emitting device 201 through the connection lead 15 and ensures that the display panel 100 can display images normally.

For example, a material of the second substrate 13 includes but is not limited to polyimide (PI).

For example, a material of the second electrodes 14 includes but is not limited to copper foil.

In some embodiments, an orthographic projection of the protruding portion 132 on a reference plane M overlaps an orthographic projection of the at least one second electrode 14 on the reference plane M, the reference plane M being parallel to the selected side surface 11cc.

It can be understood that each protruding portion 132 is arranged corresponding to at least one second electrode 14. As shown in FIGS. 4 and 5, each protruding portion 132 is arranged corresponding to one, two or three second electrodes 14.

The description here is for illustrative purposes only and is not intended to limit the present disclosure.

For example, as shown in FIG. 16, a size of the protruding portion 132 in the second direction Y is d8, and d8≥0.2 mm.

By controlling the width of the protruding portion 132 (for example, the size of the protruding portion 132 in the second direction Y shown in FIGS. 4 and 5), it avoids a problem that the size of the protruding portion 132 is too small, which causes loose adhesion between the protruding portion 132 and the first substrate 11, which causes that the second electrode 14 deviates from the preset position, which in turn causes that the connection lead 15 and the second electrode 14 may not be effectively connected. Therefore, the effective bonding area of the protruding portion 132 is guaranteed, and the tightness of attachment of the protruding portion 132 and the first substrate 11 is ensured, which ensures that the connection lead 15 and the second electrode 14 can be effectively connected. As a result, the driving signal can be transmitted to the light-emitting device 201 through the connection lead 15 to ensure that the display panel 100 can display images normally.

For example, as shown in FIG. 16, a distance between any two adjacent second electrodes 14 in the first direction X is d1, a distance between any two adjacent protruding portions 132 in the first direction X is d7, and d1>d7≥30 μm.

It should be noted that, as shown in FIG. 16, any protruding portion 132 is arranged corresponding to at least one second electrode 14; the at least one second electrode 14 to which each protruding portion 132 corresponds is regarded as an electrode group W; and the distance d1 between any two adjacent second electrodes 14 is greater than the distance d7 between any two adjacent protruding portions 132. The any two adjacent second electrodes 14 mentioned here respectively belong to two electrode groups W corresponding to the two protruding portions 132.

By controlling the distance between two adjacent protruding portions 132, the area of the side surface of the connection layer 16 is increased while ensuring the effective bonding area of the protruding portion 132, so that the connection layer 16 can dissipate heat well, and the stress at high temperature on the connection layer 16 is dispersed. Therefore, the amount of deformation of the connection layer 16 due to the influence of the ambient temperature is reduced, and the risk of breakage of the connection lead 15 during the manufacturing process of the display panel is reduced. Moreover, since the amount of deformation of the connection layer 16 due to the influence of the ambient temperature is reduced, the amount of warpage deformation of the first substrate 11 due to the influence of the deformation of the connection layer 16 is also reduced, which reduces the risk of breakage of the connection lead 15 during the manufacturing process of the display panel.

In some examples, as shown in FIG. 16, in the first direction X, the size of the protruding portion 132 is greater than a distance between outermost borders of k second electrodes 14 corresponding to the protruding portion 132. Each protruding portion 132 is arranged corresponding to k second electrodes 14, k being a positive integer greater than or equal to 1.

In the first direction X, a size of the protruding portion 132 is d15, d15≥Σ₁^{k}α_{q}+(k−1)×d1, where α_{q} is a size, in the first direction X, of a q-th second electrode 14 among the k second electrodes 14 corresponding to the protruding portion 132, Σ₁^{k}α_{q} is a sum of sizes, in the first direction X, of the k second electrodes 14 corresponding to the protruding portion 132, and k≥q≥1.

For example, as shown in FIG. 18, a size of the second electrode 14 in the first direction X is a, and a≥0.06 mm.

For example, as shown in FIG. 18, a size of the second electrode 14 in the second direction Y is b, and 0.2 mm≥b≥0.08 mm.

It can be understood that among the k second electrodes 14 to which each protruding portion 132 corresponds, the sizes of the k second electrodes 14 may all be the same; or the sizes of the k second electrodes 14 may not necessarily be the same.

In some embodiments, as shown in FIGS. 14, 15, 16 and 17, the second substrate 13 includes a plurality of first via holes K1 arranged in an array, and the first via holes K1 penetrates from an upper surface of the second substrate 13 to a lower surface of the second substrate 13. For example, the upper surface of the second substrate 13 is a surface of the second substrate 13 away from the connection layer 16, and the lower surface of the second substrate 13 is a surface of the second substrate 13 proximate to the connection layer 16.

When attaching the second substrate 13, bubbles may exist between the connection layer 16 and the second substrate 13 due to problems such as uneven attachment; and/or, when the adhesive material undergoes expansion or contraction deformation under the influence of the ambient temperature, bubbles may be created in the adhesive material; and the bubbles are discharged through the groove(s) C and/or the first via holes K1, so as to ensure the flatness and tightness of the attachment of the second substrate 13 and the connection layer 16, and in turn ensure the flatness and tightness of the attachment of the second substrate 13 and the first substrate 11. The problem of breakage of the connection lead 15 caused by bubbles generated when attaching the second substrate 13 or the problem of poor connection between the second electrode 14 and the connection lead 15 is avoided, and the reliability of the connection lead 15 is guaranteed. As a result, the driving signal can be transmitted to the light-emitting device 201 through the connection lead 15 to ensure that the display panel 100 can display images normally.

For example, as shown in FIGS. 14, 15 and 16, shapes of the first via holes K1 may be at least one of an oblique cylinder, a cylinder, a truncated cone, a prism, a frustum of a prism, or the like.

As shown in FIGS. 14, 15 and 16, any sectional shape of the first via hole K1 parallel to the second surface 11b includes but is not limited to a circle, ellipse, trapezoid, rectangle and polygon. For a single first via hole K1, shapes of any two of sections of the first via hole K1 parallel to the second surface 11b are similar or congruent.

For example, as shown in FIGS. 14, 15 and 16, the plurality of first via holes K1 arranged in an array may be in at least one of a honeycomb arrangement manner, a matrix arrangement manner, a linear arrangement manner or a circular arrangement manner. When the plurality of first via holes K1 are in a linear array, they may be arranged in a linear array in a straight line, a curve, or a polyline.

For example, as shown in FIGS. 14, 15 and 16, borders of the plurality of first via holes K1 do not overlap the border(s) of the second substrate 13.

For example, as shown in FIGS. 14, 15 and 16, a size of the first via hole K1 in the first direction X is less than or equal to the size of the second substrate 13 in the first direction X.

For example, as shown in FIGS. 14, 15 and 16, a size of the first via hole K1 in the second direction Y is less than or equal to the size of the second substrate 13 in the second direction Y.

In some examples, orthogonal projections of the plurality of first via holes K1 on the second surface 11b are located within an orthographic projection of the second substrate 13 on the second surface 11b.

For example, as shown in FIG. 17, the first via hole K1 is inclined in a set direction and penetrates through the second substrate 13, and an included angle provided by the set direction and the upper surface of the second substrate 13 is an acute angle.

In some embodiments, as shown in FIG. 15, the plurality of first via holes K1 are arranged in multiple columns in the second direction Y, and at least one side of two sides of each column of first via holes K1 in the first direction X is provided with at least one second electrode 14.

When bubbles exist between the second electrode 14 and the first substrate 11, e.g., exist between the second substrate 13 and the connection layer 16 and between the second electrode 14 and the first substrate 11, the second electrode 14 may deviate from the preset position, causing the problem that the connection lead 15 and the second electrode 14 cannot be effectively connected when the connection lead 15 is formed, so that the driving signal cannot be transmitted to the light-emitting device 201 normally, and the display panel cannot display images normally.

By providing the first via holes K1, the bubbles that exist between the second substrate 13 and the connection layer 16 and between the second electrode 14 and the first substrate 11 can be discharged through the first via holes K1, so that the second electrode 14 can be maintained at the set position, which ensures that the connection lead 15 and the second electrode 14 can be effectively connected. As a result, the driving signal can be transmitted to the light-emitting device 201 through the connection lead 15 to ensure that the display panel 100 can display images normally.

In some embodiments, as shown in FIG. 15, in the first direction X, the size of the first via hole K1 is less than a gap between two second electrodes 14 adjacent to the first via hole K1.

For example, there is a gap between an orthographic projection of the second electrode 14 on the second surface 11b of the first substrate 11 and an orthogonal projection of the first via hole K1 on the second surface 11b of the first substrate 11.

When attaching the second substrate 13, bubbles may exist between the connection layer 16 and the second substrate 13 due to problems such as uneven attachment, and the bubbles may be discharged through the first via holes K1. When the first via hole K1 and the second electrode 14 overlap, the second electrode 14 may be in contact with other conductive structure(s) in the display panel 100 through the first via hole K1 to cause a short circuit. In addition, since the first via hole K1 and the second electrode 14 overlap, the edge of the second electrode 14 may warp when the bubbles are discharged from the first via hole K1, resulting in a risk of the second electrode 14 being detached from the second substrate 13.

By controlling the size of the first via hole K1 between two adjacent second electrodes 14, the problem that the second electrode 14 may come into contact with other structures through the first via hole K1 is effectively avoided. Moreover, it is possible to avoid that the edge of the second electrode 14 is warped when bubbles are discharged through the first via holes K1, and in turn ensure the tightness of the attachment of the second electrode 14 and the second substrate 13.

It can be understood that among the plurality of first via holes K1, except for the first via holes K1 located between two adjacent second electrodes 14, sizes of the remaining first via holes K1 in the first direction X may be less than, greater than, or equal to the gap between two adjacent second electrodes 14.

In some embodiments, as shown in FIG. 17, the connection layer 16 includes a plurality of second via holes K2. The second via holes K2 penetrate from the upper surface of the connection layer 16 to the lower surface of the connection layer 16. The second via hole K2 is communicated with the first via hole K1.

When attaching the second substrate 13, bubbles may exist between the connection layer 16 and the first substrate 11 and/or between the connection layer 16 and the second substrate 13 due to problems such as uneven attachment; when the adhesive material undergoes expansion or contraction deformation under the influence of the ambient temperature, bubbles may be created in the adhesive material; and by providing the plurality of second via holes K2 respectively corresponding to the plurality of first via holes K1 in the connection layer 16, the bubbles may be discharged through the second via holes K2 and/or the first via holes K1, so as to ensure the flatness and tightness of the attachment of the second substrate 13 and the first substrate 11.

For example, the second via hole K2 and the first via hole K1 communicated therewith have the same shape, and the second via holes K2 and the first via holes K1 are in one-to-one correspondence.

For example, shapes of the second via holes K2 may be at least one of an oblique cylinder, a cylinder, a truncated cone, a prism, a frustum of a prism, or the like.

Any sectional shape of the second via hole K2 parallel to the second surface 11b includes but is not limited to a circle, ellipse, trapezoid, rectangle and polygon. For a single second via hole K2, its shapes of any two of sections parallel to the second surface 11b are similar or congruent.

For example, as shown in FIG. 17, the second via hole K2 is inclined in a set direction and penetrates through the second substrate 13, and an included angle provided by the set direction and the upper surface of the second substrate 13 is an acute angle.

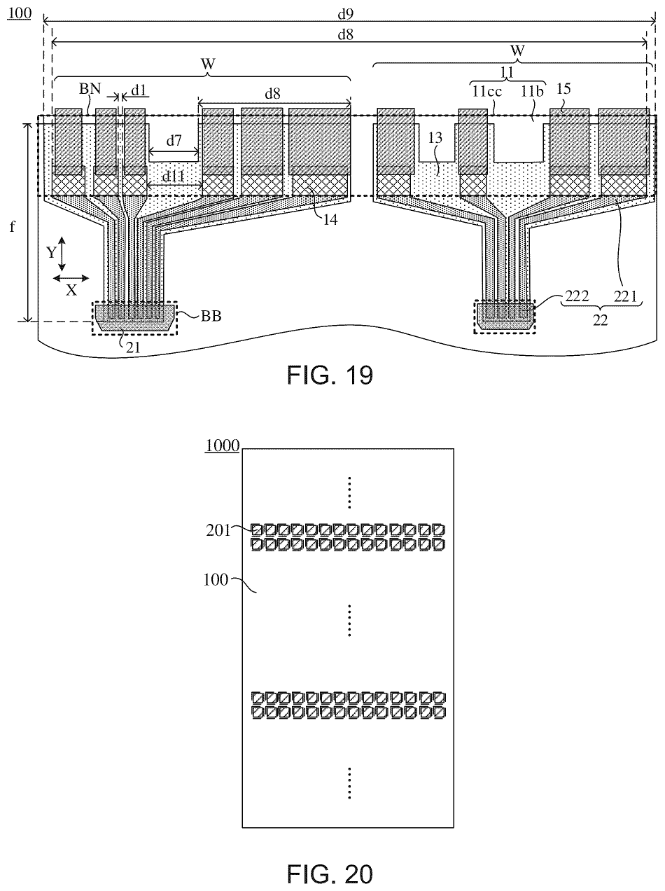

In some embodiments, as shown in FIGS. 18 and 19, the display panel 100 further includes a plurality of fan-out lines 22 disposed on the second substrate 13. A first end 221 of each fan-out line 22 is electrically connected to a second electrode 14, and a second end 222 of each fan-out line 22 is electrically connected to the driver circuit board 21.

By providing the fan-out lines 22, the overall size, in the first direction X, of signal lines (such as the second electrodes 14 or the connection leads 15) connected to the driver circuit board 21 is narrowed, so as to reduce the size of the driver circuit board 21 connected to the signal lines, and in turn reduce the thickness of the display panel 100.

It can be understood that the second electrode 13 and the fan-out line 22 can be a one-piece structure, or two parts that are electrically connected, which can be designed according to requirements. The description here is for illustrative purposes only and is not intended to limit the present disclosure.

For example, as shown in FIGS. 4, 18 and 19, the second electrode 14 may be directly connected to the driver circuit board 21, or the second electrode 14 may be connected to the driver circuit board 21 through other structure (such as the fan-out line 22).

For example, as shown in FIGS. 4, 18 and 19, multiple second electrodes 14 may be connected to the same driver circuit board 21; alternatively, multiple second electrodes 14 may be connected to multiple driver circuit boards 21, respectively.

In some embodiments, as shown in FIG. 18, a distance between any two adjacent second electrodes 14 in the first direction X is d1. The distance between the second electrodes 14 may be according to requirements. The distance d1 between any two adjacent second electrodes 14 is the same; or the distance d1 between any two adjacent second electrodes 14 is not necessarily the same.

For example, as shown in FIG. 19, the plurality of second electrodes 14 are divided into a plurality of electrode groups W, and each electrode group W includes p second electrodes 14, p being a positive integer and p≥1. A distance d11 between any two adjacent electrode groups W is greater than or equal to the distance d1 between any two adjacent second electrodes 14 in each electrode group W.

In some examples, the distance d11 between any two adjacent electrode groups W in the first direction X is greater than or equal to 0.1 mm (d11≥0.1 mm). For example, d11>d1.

By controlling the distance d1 between adjacent second electrodes 14 and the distance d11 between adjacent electrode groups W, during the process of forming the connection leads 15, the effective connection between the connection lead 15 and the corresponding second electrode 14 is ensured, and the connection lead 15 is prevented from being in contact with other second electrodes 14 adjacent to the corresponding second electrode 14, so that the short circuit caused by the same connection lead 15 being electrically connected to two or more second electrodes 14 is avoided.

For example, the size of the second substrate 13 is related to the plurality of second electrodes 14 and the plurality of fan-out lines 22. As shown in FIG. 19, orthographic projections of the second electrodes 14 and the fan-out lines 22 on the second surface 11b are located within the orthographic projection of the second substrate 13 on the second surface 11b. The size f of the second substrate 13 in the second direction Y is designed based on the sizes of the second electrodes 14 and the fan-out lines 22 in the second direction Y.

For example, as shown in FIG. 19, in the first direction X, a distance between two farthest borders of the plurality of second electrodes 14 is d8, the size of the second substrate 13 is d9, and d9>d8.

As shown in FIG. 19, the size of the second substrate 13 in the first direction X is d9, and 50 mm≥d9≥3 mm.

For example, the driver circuit board 21 includes but is not limited to a printed circuit board (PCB) or a flexible printed circuit (FPC).

For example, as shown in FIGS. 4, 18 and 19, the shape of the second substrate 13 includes but is not limited to rectangle, “T” shape and “Π” shape.

For example, as shown in FIG. 19, the second surface 11b includes a connection region BN and a bonding region BB located on a side of the connection region BN away from the selected side surface 11cc, and the connection region BN is disposed close to the selected side surface 11cc. The second electrodes 14 are located in the connection region BN, and second ends 222 of the fan-out lines 22 are located in the bonding region BB.

For example, as shown in FIG. 5, the protective layer 18 may further cover first ends 221 of the plurality of fan-out lines 22.

In some embodiments, as shown in FIG. 5, the light-emitting layer 20 includes a plurality of light-emitting devices 201, a plurality of light-emitting driver chips 202, and a protective film 203.

For example, the light-emitting devices 201 include, but are not limited to, organic light-emitting diodes (OLEDs), mini light-emitting diodes (Mini LEDs), micro light-emitting diodes (Micro LEDs), etc.

For example, the light-emitting layer 20 further includes light-emitting driver chips 202, and the light-emitting driver chips 202 are electrically connected to the driving circuit layer 19. The light-emitting driver chip 202 is configured to drive and control the light-emitting brightness of the light-emitting device 201. The pads in the driving circuit layer 19 include, for example, device pads and driver pads. Pins of the light-emitting device 201 are connected to device pads, and leads of the light-emitting driver chip 202 are connected to driver pads.

Each light-emitting driver chip 202 is configured to control one or more light-emitting devices 201. For example, each light-emitting driver chip 202 controls three light-emitting devices 201.

For example, the protective film 203 may be made of black silica gel or black resin.

The protective film 203 can protect the plurality of light-emitting devices 201 and prevent the plurality of light-emitting devices 201 from being damaged during processes after the light-emitting devices 201 are formed.

For example, as shown in FIG. 5, the protective film 203 covers the plurality of light-emitting devices 201 at least, and fills gap regions of the plurality of light-emitting devices 201.

In some examples, the protective film 203 is a film layer structure farthest from the first substrate 11 in the display panel 100. The protective film 203 covers a side of the first surface 11a of the first substrate 11, the selected side surface 11cc, and a part of the second surface 11b proximate to the selected side surface 11cc.

For example, the display panel 100 includes sub-pixels of a plurality of colors, the sub-pixels P of the plurality of colors include at least sub-pixels of a first color, sub-pixels of a second color and sub-pixels of a third color, and the first color, the second color and the third color may be three primary colors (e.g., red, green and blue). Each sub-pixel includes, for example, at least one light-emitting device 201.

The embodiments of the present disclosure further provide a display device 1000. As shown in FIG. 20, the display device 1000 includes an integrated circuit chip and the display panel 100 as described in any one of the above embodiments. The integrated circuit chip is electrically connected to the second electrodes 14 in the display panel 100.

For example, the integrated circuit chip is electrically connected to the driving circuit board 21 and is configured to output driving signals to the display panel 100, so as to drive the display panel 100 to display images.

In the display device 1000, the integrated circuit chip outputs the driving signals, and then the driving signals are transmitted to the second electrodes 14 of the display panel 100 through the driver circuit board 21. The driving signal is transmitted to the driving circuit layer 19 by sequentially passing through the second electrode 14, the connection lead 15 and the first electrode 12, and is transmitted to the light-emitting layer 20 through the driving circuit layer 19, so as to control the light-emitting device 201 in the light-emitting layer 20 to emit light. Therefore, the display device 1000 displays images.

The light-emitting devices 201 adopt Mini LEDs or Micro LEDs, which have a smaller volume; on the first substrate of the same area, the arrangement density of the light-emitting devices per unit area may be higher; and the independent driving or partitioned driving of the light-emitting devices 201 may be realized; therefore, the uniformity of display brightness is improved, and the display quality of the display device 1000 is improved.

The display device 1000 has the same structure and beneficial effects as the display panel 100 provided in some embodiments described above, and details will not be repeated here.

The embodiments of the present disclosure further provide a tiled display device 2000.

In some embodiments, as shown in FIG. 21, the tiled display device 2000 includes a plurality of display panels 100 that are tiled as described in any one of the above embodiments.

In some other embodiments, the tiled display device 2000 includes a plurality of display devices 100 that are tiled as described in any one of the above embodiments.

The following description is introduced by taking an example in which the tiled display device 2000 includes a plurality of display panels 100 that are tiled.

For example, as shown in FIG. 21, the display panel 100 is in a shape of a rectangle.

In some examples, as shown in FIG. 21, the plurality of display panels 100 in the tiled display device 2000 are arranged in an array.

As shown in FIG. 3, in the display panel 100, a plurality of first electrodes 12 are arranged side by side in the first direction X. Correspondingly, a plurality of connection leads 15 are also arranged side by side in the first direction X. Another direction that is parallel to the first surface 11a of the display panel 100 and perpendicular to the first direction X is referred to as the second direction Y.

For example, as shown in FIGS. 3 and 21, the display panel 100 includes a selected side surface 11cc.

As shown in FIG. 21, when a plurality of display panels 100 as shown in FIG. 3 are tiled, for example, the selected side surfaces 11cc of the plurality of display panels 100 are all arranged in the first direction X. In this way, among multiple display panels 100 arranged in a row in the first direction X, there is substantially no tiled gap between two adjacent display panels 100 in the first direction X; among multiple display panels 100 arranged in a column in the second direction Y, there is a tiled gap between two adjacent display panels 100. That is to say, the size of the tiled gap between two adjacent display panels 100 among multiple display panels 100 arranged in a row in the first direction X is less than the size of the tiled gap between two adjacent display panels 100 among multiple display panels 100 arranged in a column in the second direction Y.

In this way, when viewing the tiled display device 2000, the tiled gap between two adjacent display panels 100 is difficult to be viewed by the eyes within a viewing distance, so that the display image of the tiled display device 2000 is more complete, which may realize a good display effect.

For example, in the tiled display device 2000 as shown in FIG. 21, each display panel 100 includes sub-pixels of a plurality of colors, and the sub-pixels of the plurality of colors include at least sub-pixels of a first color, sub-pixels of a second color and sub-pixels of a third color. The first color, the second color and the third color are three primary colors (e.g., red, green and blue). Each sub-pixel includes, for example, at least one light-emitting device 201.

The tiled display device 2000 further has the same structure and beneficial effects as the display panel 100 provided in some embodiments described above, and details will not be repeated here.

The foregoing descriptions are merely specific implementation manners of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

What is claimed is:

1. A display panel, comprising:
a first substrate including a first surface and a second surface that are opposite to each other and a plurality of side surfaces connecting the first surface and the second surface, at least one side surface being a selected side surface; the first surface including a display region and a peripheral region located on at least one side of the display region, the peripheral region being closer to the selected side surface than the display region;
a plurality of first electrodes disposed in the peripheral region;
a second substrate disposed on the second surface;
a connection layer disposed between the first substrate and the second substrate, the connection layer bonding the first substrate and the second substrate, an orthographic projection of the connection layer on the second surface being located within an orthographic projection of the second substrate on the second surface;
a plurality of second electrodes disposed on a side of the second substrate away from the first substrate and disposed proximate to the selected side surface; and
a plurality of connection leads extending from the first surface to the second surface through the selected side surface, wherein an end of a connection lead of the plurality of connection leads is connected to a first electrode of the plurality of first electrodes, and another end of the connection lead is connected to a second electrode of the plurality of second electrodes.

2. The display panel according to claim 1, wherein the connection layer includes at least one groove penetrating from an upper surface of the connection layer to a lower surface of the connection layer.

3. The display panel according to claim 2, wherein the groove includes at least one first groove and/or at least one second groove, the first groove and the second groove extending in different directions; and
a border of the first groove and a border of the second groove do not overlap a border of the connection layer.

4. The display panel according to claim 2, wherein the groove penetrates the connection layer in a set direction, the set direction being parallel to the lower surface of the connection layer; and
the connection layer includes a plurality of grooves, and the plurality of grooves are arranged at intervals.

5. The display panel according to claim 4, wherein the grooves penetrate the connection layer in a first direction, and the grooves are located on a side of the second electrodes away from the selected side surface, the first direction being parallel to the second surface and the selected side surface; or
the grooves are of a grid-like structure.

6. The display panel according to claim 1, wherein a border of the connection layer proximate to the selected side surface overlaps a border of the second proximate to the selected side surface; or
the border of the connection layer proximate to the selected side surface is farther away from the selected side surface than the border of the second substrate proximate to the selected side surface.

7. The display panel according to claim 1, wherein the second substrate includes a body portion and a plurality of protruding portions disposed on a side of the body portion proximate to the selected side surface; an end of a protruding portion of the plurality of protruding portions is connected to the body portion, and another end of the protruding portion extends toward the selected side surface; and the plurality of the protruding portions are arranged at intervals in the first direction.

8. The display panel according to claim 7, wherein an orthographic projection of the protruding portion on a reference plane overlaps an orthographic projection of at least one second electrode on the reference plane, the reference plane being parallel to the selected side surface.

9. The display panel according to claim 1, wherein the second substrate includes a plurality of first via holes arranged in an array, and the first via holes penetrate from an upper surface of the second substrate to a lower surface of the second substrate.

10. The display panel according to claim 9, wherein the plurality of first via holes are arranged in a plurality of columns in a second direction, the second direction being perpendicular to a first direction and the selected side surface; and at least one side of two sides of each column of first via holes in the first direction is provided with at least one second electrode.

11. The display panel according to claim 10, wherein in the first direction, a size of a first via hole of the plurality of first via holes is less than a distance between two second electrodes adjacent to the first via hole.

12. The display panel according to claim 9, wherein the connection layer includes a plurality of second via holes, the second via holes penetrate from an upper surface of the connection layer to a lower surface of the connection layer, and a second via hole of the plurality of second via holes is communicated with a first via hole of the plurality of first via holes.

13. The display panel according to claim 1, further comprising:
a buffer layer disposed on the side of the second substrate away from the first substrate and covering an edge portion of the second substrate proximate to the selected side surface, wherein
the connection lead is connected to the second electrode across the buffer layer.

14. The display panel according to claim 13, wherein the buffer layer does not overlap the second electrodes, and the buffer layer and the selected side surface have a gap therebetween.

15. The display panel according to claim 13, wherein the buffer layer includes a first slope and a second slope that are connected; in a second direction and a direction pointing from the selected side surface to the second substrate, a height of the first slope gradually increases, and a height of the second slope gradually decreases; and the first slope and the second slope are smoothly connected.

16. The display panel according to claim 15, wherein a slope angle of the first slope and a slope angle of the second slope are each an acute angle.

17. The display panel according to claim 13, wherein the edge portion of the second substrate proximate to the selected side surface is extended with respect to a border of the connection layer proximate to the selected side surface; the edge portion of the second substrate, a side surface of the connection layer and the second surface enclose a gap region; and a portion of the buffer layer fills the gap region.

18. A display device, comprising: an integrated circuit chip and the display panel according to claim 1, the integrated circuit chip being electrically connected to the second electrodes.

19. A tiled display device, comprising a plurality of display devices that are tiled according to claim 18.

20. A tiled display device, comprising a plurality of display panels that are tiled according to claim 1.
